(19) United States
(12) Patent Application Publication
(10) Pub. No.: US 2026/0073498 A1
(43) Pub. Date: Mar. 12, 2026

(54) METHOD FOR COMPARING 3D REPRESENTATIONS

(71) Applicants: Inventec (Pudong) Technology Corporation, Shanghai (CN); INVENTEC CORPORATION, TAIPEI CITY (TW)

(72) Inventors: Zhong-Qi CAI, TAIPEI CITY (TW); Yu-Chi LAI, TAIPEI CITY (TW); Wei-Chao CHEN, TAIPEI CITY (TW); Chih-Pin WEI, TAIPEI CITY (TW); Kai-Jyun JIANG, TAIPEI CITY (TW); Ming-Chi CHANG, TAIPEI CITY (TW); Chung-Sheng NI, TAIPEI CITY (TW)

(21) Appl. No.: 19/236,966

(22) Filed: Jun. 12, 2025

(30) Foreign Application Priority Data
Sep. 11, 2024 (CN) 202411274314.0

(51) Int. Cl. G06T 7/00; G06T 7/33; G06T 15/00

(52) U.S. Cl. CPC G06T 7/0002; G06T 7/344; G06T 15/00; G06T 2200/04; G06T 2207/30141

(57) ABSTRACT

A comparison method for 3D representations includes steps of: determining a first deformation of a corresponding layer of a second 3D representation according to linear data of a corresponding layer of a first 3D representation and the second 3D representation; generating multiple transformation matrices configured to transform the corresponding layer of the second 3D representation into multiple transformed layers, where multiple second deformations of the multiple transformed layers are less than the first deformation; selecting a specific transformation matrix from the multiple transformation matrices to perform a transformation to generate a specific transformed layer; and comparing the specific transformed layer with the corresponding layer of the first 3D representation to find a difference feature between the specific transformed layer and the corresponding layer of the first 3D representation.

### CROSS-REFERENCE TO RELATED APPLICATION

This application claims priority to and the benefit of Chinese patent application No. 202411274314.0, filed on Sep. 11, 2024, the entire content of which is incorporated herein by reference as if fully set forth below in its entirety and for all applicable purposes.

### BACKGROUND

### Field of Disclosure

The disclosure generally relates to a method for comparing 3D representations, particularly a 3D representation comparison method for mechanical design.

### Description of Related Art

In the three-dimensional (3D) mechanical design of a printed circuit board assembly (PCA), customers typically provide mechanical engineers with 3D representations (such as CAD files or DXF files) of different versions of electronic components as design references. The mechanical engineers then modify the design according to the differences between these 3D representations. However, since the PCA involves multiple electronic components, a large number of 3D representations must be considered to complete the mechanical design of the PCA. Moreover, these 3D representations often have dozens of layers, with each layer containing a large number of line segments. The current implementation of comparing 3D representations by human eyes to inspect the difference between the 3D representations is time-consuming, misses the subtle differences, and incorrectly alters the 3D representations.

Therefore, the current implementation has many shortcomings, and an improved method for comparing 3D representations is required.

### SUMMARY

The disclosure can be more fully understood by reading the following detailed description of the embodiments, with reference made to the accompanying drawings as described below. It should be noted that the features in the drawings are not necessarily to scale. In fact, the dimensions of the features may be arbitrarily increased or decreased for clarity of discussion.

One aspect of the present disclosure is to provide a 3D representation comparison method. The 3D representation comparison method includes steps of: according to multiple linear data of a corresponding layer of a first 3D representation and multiple linear data of a corresponding layer of a second 3D representation, determining a first deformation of the corresponding layer of the second 3D representation relative to the corresponding layer of the first 3D representation; according to the multiple linear data of the corresponding layer of the first 3D representation, the multiple linear data of the corresponding layer of the second 3D representation, and the first deformation, generating multiple transformation matrices for transforming the corresponding layer of the second 3D representation into multiple transformed layers, wherein multiple second deformations of the multiple transformed layers relative to the corresponding layer of the first 3D representation are less than the first deformation; selecting a specific transformation matrix from the multiple transformation matrices to perform a transformation to generate a specific transformed layer of the multiple transformed layers; and comparing the specific transformed layer with the corresponding layer of the first 3D representation to find a difference feature between the specific transformed layer and the corresponding layer of the first 3D representation.

In some embodiments, according to the multiple linear data of the corresponding layer of the first 3D representation and the multiple linear data of the corresponding layer of the second 3D representation, determining the first deformation of the corresponding layer of the second 3D representation relative to the corresponding layer of the first 3D representation includes according to the multiple linear data of the corresponding layer of the first 3D representation, determining multiple linear ranges and multiple line forms of the corresponding layer of the first 3D representation; according to the multiple linear data of the corresponding layer of the second 3D representation, determining multiple linear ranges and multiple line forms of corresponding layer of the second 3D representation; and according to the multiple linear ranges and the multiple line forms of the corresponding layer of the first 3D representation and the multiple linear ranges and the multiple line forms of the corresponding layer of the second 3D representation, determining the first deformation.

In some embodiments, the 3D representation comparison method further includes, according to the multiple linear ranges and the multiple line forms of the corresponding layer of the first 3D representation and multiple linear ranges and multiple line forms of the multiple transformed layers, determining the multiple second deformations.

In some embodiments, comparing the specific transformed layer with the corresponding layer of the first 3D representation to find the difference feature between the specific transformed layer and the corresponding layer of the first 3D representation includes when a first line segment of the corresponding layer of the first 3D representation overlapping with a second line segment of the specific transformed layer, determining that the second line segment is a common feature of the specific transformed layer and the corresponding layer of the first 3D representation.

In some embodiments, the 3D representation comparison method further includes when the second 3D representation comprising a non-corresponding layer, determining that the non-corresponding layer is the difference feature of the second 3D representation and the first 3D representation.

In some embodiments, the 3D representation comparison method further includes aligning a first coordinate system of the first 3D representation with a second coordinate system of the second 3D representation.

In some embodiments, the 3D representation comparison method of aligning a first coordinate system of the first 3D representation with a second coordinate system of the second 3D representation includes aligning a center position of the first 3D representation with a center position of the second 3D representation.

In some embodiments, according to a voting algorithm, selecting the specific transformation matrix from the multiple transformation matrices to perform a transformation to generate the specific transformed layer of the multiple transformed layers.

In some embodiments, the specific transformed layer has the smallest of the multiple second deformations.

One aspect of the present disclosure is to provide a 3D representation comparison method. The 3D representation comparison method includes steps of: according to multiple linear data of a corresponding layer of a first 3D representation and multiple linear data of a corresponding layer of a second 3D representation, determining a first deformation of the corresponding layer of the second 3D representation relative to the corresponding layer of the first 3D representation; according to the multiple linear data of the corresponding layer of the first 3D representation, the multiple linear data of the corresponding layer of the second 3D representation, and first deformation, generating a transformation matrix configured to transform the corresponding layer of the second 3D representation into a transformed layer, wherein a second deformation of the transformed layer relative to the corresponding layer of the first 3D representation is less than the first deformation, and the transformation matrix is configured to perform a transformation to generate the transformed layer; and comparing the transformed layer with the corresponding layer of the first 3D representation to find a difference feature between the transformed layer and the corresponding layer of the first 3D representation.

### BRIEF DESCRIPTION OF THE DRAWINGS

The patent or application file contains at least one drawing executed in color. Copies of this patent or patent application publication with color drawing(s) will be provided by Office upon request and payment of the necessary fee. The disclosure can be more fully understood by reading the following detailed description of the embodiment, with reference made to the accompanying drawings as follows.

FIG. 1 is a flowchart of a 3D representation comparison method according to some embodiments of the present disclosure;

FIG. 2 is a flowchart of the operation of an overlaying computation and the layer difference comparison according to some embodiments of the disclosure;

FIG. 3 is a schematic diagram of a difference determination method according to some embodiments of the present disclosure;

FIG. 4 is a schematic diagram illustrating a display method according to some embodiments of the present disclosure; and

FIG. 5 is a flowchart of operations of an overlaying computation and the layer difference comparison according to some embodiments of the disclosure.

### DETAILED DESCRIPTION

Reference will now be made in detail to the present embodiments of the disclosure, examples of which are illustrated in the accompanying drawings. However, the embodiments provided herein are intended as illustrative only since numerous modifications and variations therein will be apparent to those skilled in the art. The description of the operation does not intend to limit the operation sequence. Any structures resulting from the recombination of components with equivalent effects are within the scope of the present disclosure. In addition, drawings are only for illustration and not plotted according to the original size. Wherever possible, the same reference numbers are used in the drawings and the specification to refer to the same or the like parts for better understanding.

Terms used throughout the specification are used for describing specific embodiments without limiting the scope of the disclosure. Terms of the singular form, such as “one”, “this”, “the”, and the like, may include meaning in the plural form.

Terms used throughout the specification and the claims such as “including”, “comprising”, “having”, and the like, used herein are open-ended, that is, including but not limited to.

Terms used throughout the specification and the claims typically have common meanings for each of the terms used in this field, in the present disclosure and special contents, unless specially noted. Some terms used for describing the present disclosure will be discussed in the following statement or other paragraphs to provide additional guidance to those skilled in the art regarding the description of the present disclosure.

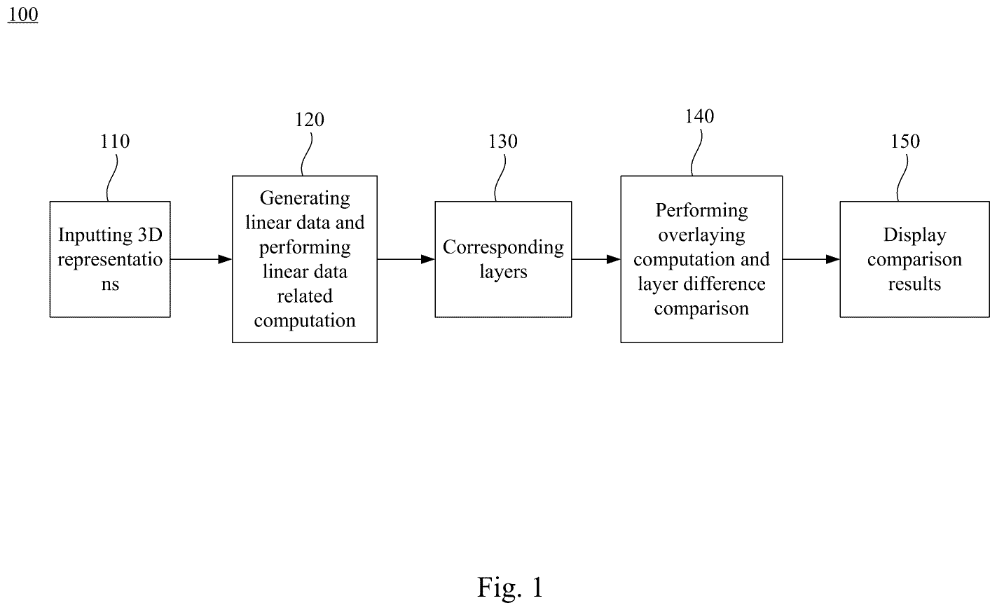

Reference is made to FIG. 1. FIG. 1 is a flowchart of a 3D representation comparison method 100 according to some embodiments of the present disclosure. First, in operation 110, two 3D representations to be compared are inputted into a 3D representation processing module (not shown in figures) configured to perform the 3D representation comparison method 100 of the disclosure. Specifically, the 3D representation processing module is stored in a storage unit of an electronic device and performed by a processor electrically connected to the storage unit. In the embodiment, the electronic device may be a desktop computer, a notebook computer, a mobile phone, and so on; the storage unit may be a hard disk drive (HDD), a solid state drive (SSD), and the like. The 3D representation processing module executes operations 120 to 150 sequentially to perform the 3D representation comparison method 100.

In operation 120, linear data Ldata1 is generated and a linear data related computation is performed to generate linear data Ldata2. In other words, the two 3D representations inputted are transformed into the linear data Ldata1, and these linear data Ldata1 are used to compute the linear data related computation to generate the linear data Ldata2. More specifically, the two 3D representations inputted include a 3D representation gh_1 and a 3D representation gh_2 (not shown in figures), each of the 3D representation gh_1 and the 3D representation gh_2 includes multiple layers, and the multiple layers include multiple line segments. The linear data of a specific layer of the 3D representation gh_1 or the 3D representation gh_2 includes positions of two endpoints of each of the line segments and the lengths of the line segments of the specific layer, where the line segments may be a straight-line form or a curved form. In other words, the linear data of the specific layer includes the positions of two endpoints of each of the line segments of the straight-line form and the curved form and the lengths of the line segments of the straight-line form and the curved form of the specific layer. Furthermore, when the line segments include the line segments of the curved form, in addition to the positions of the two endpoints of each of the line segments and the lengths of the line segments of the specific layer, the linear data of the specific layer further includes the position of at least one interior point of each of the line segments of the curved form, such as the position of the middle point of the line segment of the curved form.

Furthermore, the linear data related computation includes the alignment of coordinate systems of the two 3D representations. More specifically, the 3D representations gh_1 has the coordinate system Ref_1, and the 3D representation gh_2 has the coordinate system Ref_2. In the linear data related computation, the X-axis direction of the coordinate systems Ref_1 and Ref_2 are aligned to point to the same direction, the Y-axis direction of the coordinate systems Ref_1 and Ref_2 are aligned point to the same direction, and the Z-axis direction of the coordinate systems Ref_1 and Ref_2 are aligned to point to the same direction. In some embodiments, the alignment may be implemented by a rotation matrix that rotates the coordinate system Ref_2.

Furthermore, in some embodiments, the center of the 3D representation gh_1 and the center of the 3D representation gh_2 are aligned, such that the coordinate system Ref_1 and the coordinate system Ref_2 are aligned. That is, the center of the 3D representation gh_1 and the center of the 3D representation gh_2 are located at the same point. In another embodiment, the origin of the coordinate system Ref_1 and the origin of the coordinate system Ref_2 are aligned such that the coordinate system Ref_1 and the coordinate system Ref_2 are aligned. More specifically, the 3D representation gh_1 and the 3D representation gh_2 respectively have a specific point, and the specific points are respectively set to be the origins of the coordinate system Ref_1 and the coordinate system Ref_2. In some embodiments, a shift matrix is applied to the coordinate system Ref_2 to align the center of the 3D representation gh_2 with the center of the 3D representation gh_1, or align the origin of the coordinate system Ref_2 with the origin of the coordinate system Ref_1.

In some embodiments, if the coordinate systems transformed from the 3D representations are aligned with each other, the linear data related computation mentioned above may be omitted. In this case, the linear data Ldata1 is equivalent to the linear data Ldata2.

In operation 130, making the layer of the 3D representation gh_1 correspond to the layer of the 3D representation gh_2 is performed. More specifically, in the process of designing each version of the 3D representations, each layer of the 3D representations is named or tagged with a code for identifying the layer. In operation 130, the layers with the same names or codes are set to be the layers to be compared with each other. For example, the 3D representations gh_1 and gh_2 have the layer that is named the first layer, the first layer of the 3D representation gh_1 and the first layer of the 3D representation gh_2 are two layers corresponding to each other. Therefore, in the disclosure, the first layer is also called a corresponding layer cL.

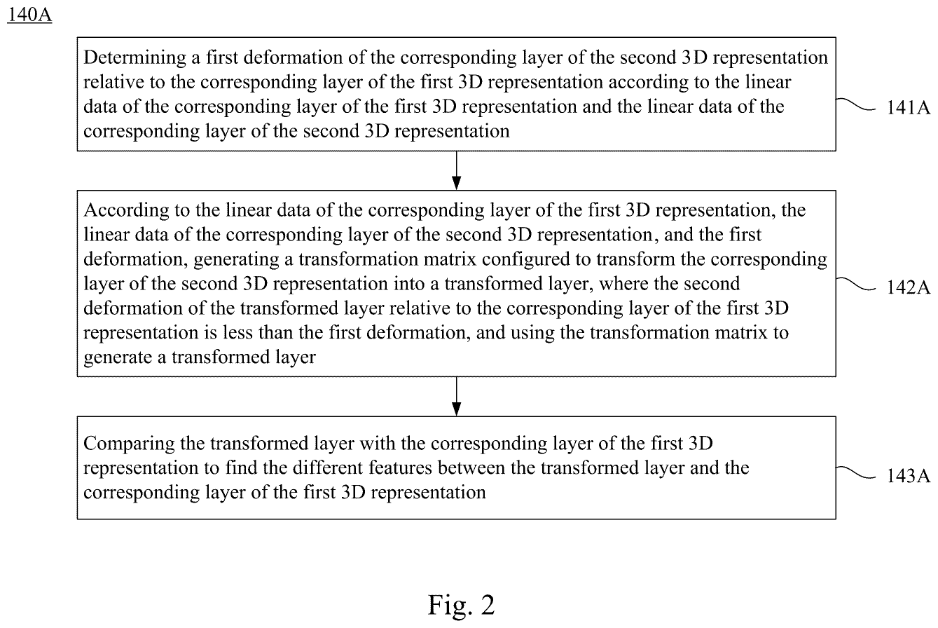

In the following statement, reference is made to FIG. 1 and FIG. 2. As shown in FIG. 1, in operation 140 the overlaying computation and the layer difference comparison are performed, and FIG. 2 is a flowchart of operation 140A of the overlaying computation and the layer difference comparison according to some embodiments of the disclosure. In one embodiment, operation 140A corresponds to operation 140 of FIG. 1. The operation 140A includes steps 141A to 143A. However, steps of operation 140A may not be performed in the order shown in FIG. 2. In other words, steps in FIG. 2 may be added, substituted, reordered, and/or omitted within the scope of the embodiments of the disclosure.

In step 141A, determining a deformation DF1 of the corresponding layer cL of the 3D representation gh_2 relative to the corresponding layer cl of the 3D representation gh_1 according to the multiple linear data of the corresponding layer cL of the 3D representation gh_1 and the multiple linear data of the corresponding layer cL of the 3D representation gh_2. More specifically, the linear data Ldata2 generated in operation 120 includes the multiple linear data Ld2_g1 of the corresponding layer cl of the 3D representation gh_1 and the multiple linear data Ld2_g2 of the corresponding layer cL of the 3D representation gh_2.

The linear data Ld2_g1 or Ld2_g2 include the positions of the endpoints of the line segments of the curved form and the straight-line form and the positions of the at least one interior point of each line segment of the curved form. In some embodiments, the deformation DF1 is determined according to the positions of the endpoints and the interior points. For example, in the case that position vectors represent the positions of the endpoints and the interior points, the positions of the endpoints and the interior points of the linear data Ld2_g1 are [symbol] , [symbol] , . . . , [symbol] , and the positions of the endpoints and the interior points of the linear data Ld2_g2 are [symbol] , [symbol] , . . . , [symbol] . The notation [symbol] is the one of the linear data Ld2_g2 whose position of the endpoints and the interior points are closest to [symbol] The notation [symbol] is the one of the linear data Ld2_g2 whose position of the endpoints and the interior points are closest to [symbol] , and the like. The notation [symbol] is the one of the linear data Ld2_g2 whose position of the endpoints and the interior points are closest to [symbol] . The deformation DF1 is the mean square root of the length of corresponding vectors ( [symbol] - [symbol] ), ( [symbol] - [symbol] ), . . . , ( [symbol] - [symbol] ).

Furthermore, in some embodiments, the deformation DF1 is computed according to a unit of the line segment. The line segment may be determined by the linear range and the line form of the line segments. Specifically, according to the linear range and the line form of the line segment L1 of the corresponding layer cl of the 3D representation gh_1 and the linear range and the line form of the line segment L2 of the corresponding layer cL of the 3D representation gh_2, the deformation of the segment L2 relative to the segment L1 is computed; according to the linear range and the line form of the line segment L3 of the corresponding layer cl of the 3D representation gh_1 and the linear range and the line form of the line segment L4 of the corresponding layer cl of the 3D representation gh_2, the deformation of the segment L4 relative to the segment L3 is computed. Similarly, the process proceeds until the deformations of all the line segments of the corresponding layer of the 3D representation gh_2 are obtained. Subsequently, the deformation DF1 is computed according to the deformation of the line segments L2, L4, and so on. In some embodiments, the deformation DF1 may be the sum of the deformation of the line segments L2, L4, and so on.

Furthermore, two endpoints of a segment may determine the linear range. The line form may include the straight-line form and/or the curved form. The curved form may include arcs, spline-like curves, and the like. An arc may be determined by two endpoints and one interior point. A spline-like curve may be determined by two endpoints and two interior points.

In other words, the multiple linear ranges and the multiple line forms of the corresponding layer cL of the 3D representation gh_1 are determined according to the linear data Ld2_g1 first, the multiple linear ranges and the multiple line forms of the corresponding layer cl of the 3D representation gh_2 are determined according to the linear data Ld2_g2, and then the deformation DF1 is determined according to the multiple linear ranges and the multiple line forms of the corresponding layer cL of the 3D representation gh_1 and the multiple linear ranges and the multiple line forms of the corresponding layer cl of the 3D representation gh_2.

However, it should be noted that the method of computing the deformation DF1 described above is provided as some examples to facilitate understanding of the 3D representation comparison method 100, and the examples are not intended to limit the scope of the disclosure. A person having ordinary skill in the art may select an appropriate algorithm to compute the deformation DF1 based on practical conditions.

In step 142A, according to the multiple linear data of the corresponding layer cl of the 3D representation gh_1, the multiple linear data of the corresponding layer cL of the 3D representation gh_2, and the deformation DF1, a transformation matrix is generated configured to transform the corresponding layer cL of the 3D representation gh_2 into a transformed layer TL, where the deformation DF2 of the transformed layer TL relative to the corresponding layer cL of the 3D representation gh_1 is less than the deformation DF1. In brief, the transformation matrix is used to overlap the corresponding layer cl of the 3D representation gh_2 with the corresponding layer cL of the 3D representation gh_1. In other words, the transformation matrix is used to generate the transformed layer TL that overlaps as closely as possible with the corresponding layer cL of the 3D representation gh_1.

Specifically, by applying the automated programming and iterative computation, the constraint condition is found: the transformation matrix that may compute the deformation DF2, which is smaller than the deformation DF1. The method for computing the deformation DF2 is the same as the computation of the deformation DF1. The difference is that, in the process of computing the deformation DF2, the corresponding layer cL of the 3D representation gh_2 is replaced with the transformed layer TL. For brevity, the details for computing the deformation DF2, being identical to the computation of the deformation DF1, are not repeated herein.

Furthermore, the transformation matrix is applied to generate the transformed layer TL to proceed to the subsequent step 143B of comparing the difference between layers.

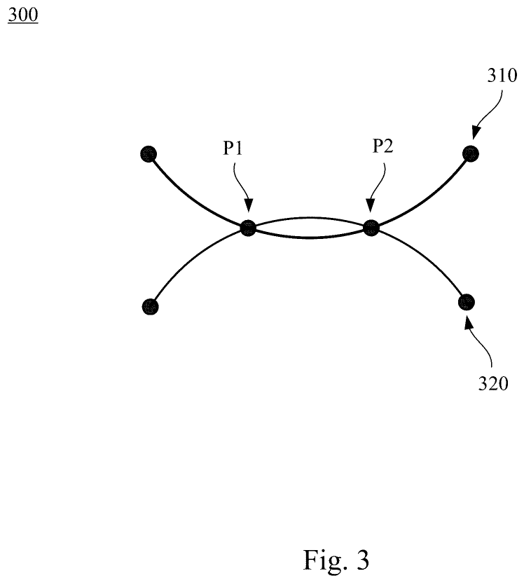

Reference is made to FIG. 1 and FIG. 3. FIG. 3 is a schematic diagram of a difference determination method 300 according to some embodiments of the present disclosure. In step 143A, the transformed layer TL is compared with the corresponding layer cL of the 3D representation gh_1 to find the difference features between the transformed layer TL and the corresponding layer cl of the 3D representation gh_1. Specifically, the difference determination method 300 is used to find the difference features between the transformed layer TL and the corresponding layer cL of the 3D representation gh_1. As shown in FIG. 3, the layer 310 and the layer 320 overlap on the line segments P1 and P2, so the line segments P1 and P2 are common features of the layer 310 and the layer 320. On the contrary, the part of the layer 310 not overlapping with the layer 320 and the part of the layer 320 not overlapping with the layer 310 are determined to be the difference features.

In other words, when the line segment L_g1 of the corresponding layer cl of the 3D representation gh_1 is overlapped with the line segment L_TL of the transformed layer TL, the line segment L_TL is determined to be the common feature. When the line segment L_g1 of the corresponding layer cl of the 3D representation gh_1 is not overlapped with the line segment L_TL of the transformed layer TL, the line segment L_TL is determined to be the difference feature. In some embodiments, when the deformation of the line segment L_TL relative to the line segment L_g1 is less than 0.1 times the deformation DF2, the line segment L_TL is regarded as being overlapped with the line segment L_g1. When the deformation of the line segment L_TL relative to the line segment L_g1 is greater than or equal to 0.1 times the deformation DF2, the line segment L_TL is regarded as not being overlapped with the line segment L_g1.

Furthermore, in some embodiments, one of the 3D representation gh_1 or the 3D representation gh_2 contains a second layer while the other does not contain the second layer. In the case, the second layer is called a non-corresponding layer (noncL). When the 3D representation gh_1 or the 3D representation gh_2 contains the non-corresponding layer, the non-corresponding layer is determined to be the difference feature between the 3D representation gh_1 and the 3D representation gh_2.

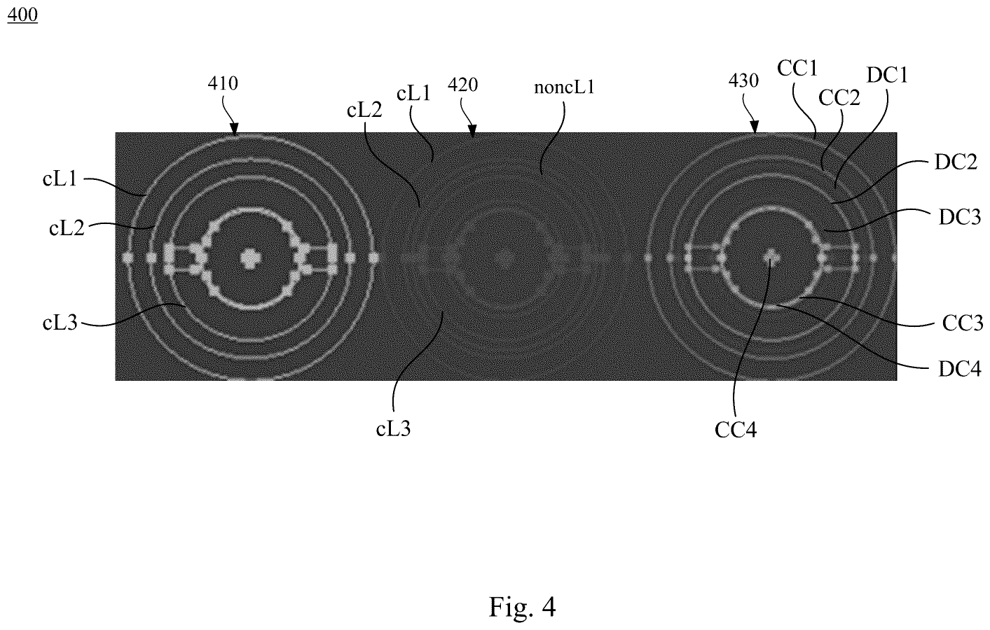

Reference is made to FIG. 1 and FIG. 4. FIG. 4 is a schematic diagram illustrating a display method 400 according to some embodiments of the present disclosure. After performing operation 140A, operation 150 is performed. In operation 150, the comparison result is displayed. Specifically, in some embodiments, the display method 400 is applied to show the comparison result. The following description shows the details of the display method 400.

In FIG. 4, the 3D representations 410 and 420, respectively, correspond to the 3D representations gh_1 and gh_2 mentioned above. The 3D representations 410 and 420 include the corresponding layers cL1 to cL3. The 3D representation 420 further includes the non-corresponding layer noncL1. In other words, the operations described above for processing the corresponding layer cL may also be applied to the layers cL1 to cL3. Similarly, the operations or steps for the non-corresponding layer noncL may also be applied to the non-corresponding layer noncL. After operations 110 to 150, the comparison result 430 shows the difference between the 3D representations 410 and the 3D representations 420.

When a line segment in the layers cL1, L2, or cL3 is determined to be a common feature, the green color is shown, such as the common features CC1 to CC4 in the comparison result 430. When a line segment is determined to be a difference feature, the original color of the line segment is shown. For example, the line segment is contained in the 3D representation 420 which is the difference feature, so the line segment is displayed in red (e.g., the difference features DC1, DC3); the line segment is contained in the 3D representation 410 which is the difference feature, so the line segment is displayed in blue (e.g., the difference features DC2, DC4).

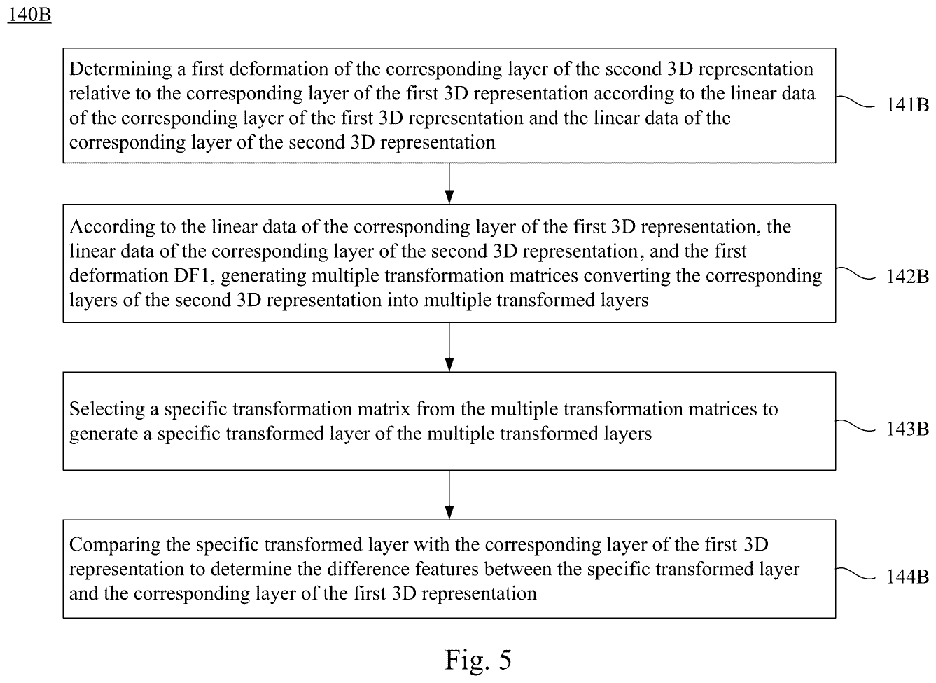

Reference is made to FIG. 1 and FIG. 5. FIG. 5 is a flowchart of operations 140B of an overlaying computation and the layer difference comparison according to some embodiments of the disclosure. Similar to operation 140A, the details of operation 140B may be referred to as operation 140 in FIG. 1. In other words, operation 140A may be replaced with operation 140B. In some embodiments, the person having ordinary skill in the art may select operation 140A or operation 140B through a user interface, keyboard, or mouse to implement the 3D representation comparison method 100.

Specifically, operation 140B includes steps 141B to 144B. Since step 141B is identical to step 141A in operation 140A, it is not repeated herein. However, the steps in operation 140B are not necessarily performed in the order shown in FIG. 5. That is, within the scope and spirit of the embodiments, steps may be added, substituted, reordered, and/or omitted as appropriate.

In step 142B, according to the linear data of the corresponding layer cl of the 3D representation gh_1, the linear data of the corresponding layer cl of the 3D representation gh_2, and the deformation DF1, multiple transformation matrices configured to convert the corresponding layers cl of the 3D representation gh_2 into multiple transformed layers TL are generated. The multiple deformations DF2 of the multiple transformed layers TL relative to the corresponding layers cL of the 3D representation gh_1 are less than the deformation DF1. Furthermore, each transformation matrix corresponds one-to-one to the transformed layer and the deformation DF2.

Compared with step 142A, the difference between step 142B and step 142A is that multiple transformation matrices are generated in step 142B instead of generating a single transformation matrix. Except for the point, the other description of step 142A is applied to step 141A and is not repeated herein. The difference indicates that the constraint condition is satisfied: the transformation matrix computing the deformation DF2, being less than the deformation DF1, is not unique. The transformation matrix may exist in different varieties. In this condition, an appropriate matrix may be selected according to specific selection rules or additional constraints.

In step 143B, a specific transformation matrix is selected from the multiple transformation matrices, and the selected one is applied to perform transformation to generate a specific transformed layer of the multiple transformed layers. In some embodiments, the transformation matrix with the smallest deformation DF2 is taken as the specific transformation matrix for the transformation process. In some embodiments, a voting algorithm is used to perform step 143B. That is, according to the voting algorithm, the multiple transformation matrices are scored, and the transformation matrix having the highest score is selected to be the specific transformation matrix.

In step 144B, the specific transformed layer is compared with the corresponding layer cL of the 3D representation gh_1 to determine the difference features between the specific transformed layer and the corresponding layer cl of the 3D representation gh_1. Compared with step 143A, the difference between step 144B and step 143A is that the layer difference comparison is performed by the specific transformed layer generated by the selected transformation matrix. It should be noted that the embodiments of the transformed layers TL in step 143A may also be applied to the specific transformed layer of step 144B.

Accordingly, the present disclosure provides a programmatic method for 3D representation comparison, which significantly reduces manual effort and offers convenience for mechanical engineers when modifying mechanical designs, and effectively addresses the deficiencies of prior technologies.

Although the present disclosure provides the details through the above-described embodiments, it does not preclude other feasible implementations. Therefore, the claimed scope of the present disclosure shall be defined by the claims appended hereto, and shall not be limited by the foregoing embodiments.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A 3D representation comparison method, comprising:
according to multiple linear data of a corresponding layer of a first 3D representation and multiple linear data of a corresponding layer of a second 3D representation, determining a first deformation of the corresponding layer of the second 3D representation relative to the corresponding layer of the first 3D representation;
according to the multiple linear data of the corresponding layer of the first 3D representation, the multiple linear data of the corresponding layer of the second 3D representation, and the first deformation, generating multiple transformation matrices configured to transform the corresponding layer of the second 3D representation into multiple transformed layers, wherein multiple second deformations of the multiple transformed layers relative to the corresponding layer of the first 3D representation are less than the first deformation;
selecting a specific transformation matrix from the multiple transformation matrices to perform a transformation to generate a specific transformed layer of the multiple transformed layers; and
comparing the specific transformed layer with the corresponding layer of the first 3D representation to find a difference feature between the specific transformed layer and the corresponding layer of the first 3D representation.

2. The 3D representation comparison method of claim 1, wherein according to the multiple linear data of the corresponding layer of the first 3D representation and the multiple linear data of the corresponding layer of the second 3D representation, determining the first deformation of the corresponding layer of the second 3D representation relative to the corresponding layer of the first 3D representation comprises:
according to the multiple linear data of the corresponding layer of the first 3D representation, determining multiple linear ranges and multiple line forms of the corresponding layer of the first 3D representation;
according to the multiple linear data of the corresponding layer of the second 3D representation, determining multiple linear ranges and multiple line forms of the corresponding layer of the second 3D representation; and
according to the multiple linear ranges and the multiple line forms of the corresponding layer of the first 3D representation and the multiple linear ranges and the multiple line forms of the corresponding layer of the second 3D representation, determining the first deformation.

3. The 3D representation comparison method of claim 2, further comprising:
according to the multiple linear ranges and the multiple line forms of the corresponding layer of the first 3D representation and multiple linear ranges and multiple line forms of the multiple transformed layers, determining the multiple second deformations.

4. The 3D representation comparison method of claim 1, wherein comparing the specific transformed layer with the corresponding layer of the first 3D representation to find the difference feature between the specific transformed layer and the corresponding layer of the first 3D representation comprises:
when a first line segment of the corresponding layer of the first 3D representation overlapping with a second line segment of the specific transformed layer, determining that the second line segment is a common feature of the specific transformed layer and the corresponding layer of the first 3D representation.

5. The 3D representation comparison method of claim 1, further comprising:
when the second 3D representation comprising a non-corresponding layer, determining that the non-corresponding layer is the difference feature of the second 3D representation and the first 3D representation.

6. The 3D representation comparison method of claim 1, further comprising:
aligning a first coordinate system of the first 3D representation with a second coordinate system of the second 3D representation.

7. The 3D representation comparison method of claim 6, wherein aligning the first coordinate system of the first 3D representation with the second coordinate system of the second 3D representation comprises:
aligning a center position of the first 3D representation with a center position of the second 3D representation.

8. The 3D representation comparison method of claim 1, further comprising according to a voting algorithm, selecting the specific transformation matrix from the multiple transformation matrices to perform a transformation to generate the specific transformed layer of the multiple transformed layers.

9. The 3D representation comparison method of claim 1, wherein the specific transformed layer has the smallest one of the multiple second deformations.

10. A 3D representation comparison method, comprising:
according to multiple linear data of a corresponding layer of a first 3D representation and multiple linear data of a corresponding layer of a second 3D representation, determining a first deformation of the corresponding layer of the second 3D representation relative to the corresponding layer of the first 3D representation;
according to the multiple linear data of the corresponding layer of the first 3D representation, the multiple linear data of the corresponding layer of the second 3D representation, and first deformation, generating a transformation matrix configured to transform the corresponding layer of the second 3D representation into a transformed layer, wherein a second deformation of the transformed layer relative to the corresponding layer of the first 3D representation is less than the first deformation, and the transformation matrix is configured to perform a transformation to generate the transformed layer; and
comparing the transformed layer with the corresponding layer of the first 3D representation to find a difference feature between the transformed layer and the corresponding layer of the first 3D representation.
